(19) United States
(12) Patent Application Publication
(10) Pub. No.: US 2012/0268118 A1
(43) Pub. Date: Oct. 25, 2012

(54) METHOD FOR CAPTURING MR IMAGE DATA AND CORRESPONDING COMBINED MR/ET FACILITY

(75) Inventors: Matthias Fenchel, Erlangen (DE); Kirstin Jattke, Nurnberg (DE)

(73) Assignee: SIEMENS AKTIENGESELLSCHAFT, Munich (DE)

(21) Appl. No.: 13/445,333

(22) Filed: Apr. 12, 2012

(30) Foreign Application Priority Data
Apr. 21, 2011 (DE) 10 2011 007 871.1

(51) Int. Cl. G01R 33/56

(52) U.S. Cl. 324/307

(57) ABSTRACT

MR image data relating to a volume section of an examination object is determined. Image data relating to this volume section is also captured by way of a true-to-original tomographic method. The MR image data is compared with the image data. Depending on the results of this comparison, either the MR image data is corrected such that the MR image data matches the image data as closely as possible, or parameters that are used during the capture of the MR image data are modified such that, when the MR image data of the predefined volume section is captured again using the modified parameters, the newly captured MR image data matches the image data as closely as possible.

### PRIORITY STATEMENT

The present application hereby claims priority under 35 U.S.C. §119 to German patent application number DE 10 2011 007 871.1 filed Apr. 21, 2011, the entire contents of which are hereby incorporated herein by reference.

### FIELD

At least one embodiment of the present invention generally relates to the capture of MR image data with reference to image data that has been captured by way of a true-to-original tomographic method, and/or a combined MR/ET facility that has been configured correspondingly.

### BACKGROUND

It is known that MR images do not constitute a geometrically accurate representation. Due to the assignment of the raw data that is captured in the frequency space (k-space) to the location space, due to incorrect deviations in the gradient linearity and due to the inhomogeneity of the basic magnetic field, the MR images are usually distorted because a magnetic resonance installation measures frequencies in the MHz range and does not measure geometric information. Depending on the sequence technique, this results in MR images providing more or less inaccurate geometric representations, echo planar imaging (EPI) in particular being one of the sequence techniques that react particularly sensitively to the effects described above.

### SUMMARY

At least one embodiment of the present invention improves the geometric representational accuracy of MR images (i.e. the accuracy with which the MR images depict geometric realities in the volume section that is depicted) relative to the prior art.

According to at least one embodiment of the invention, a method for capturing MR image data is disclosed; a combined MR/ET facility is disclosed; a computer program product is disclosed and an electronically readable data medium is disclosed. The dependent claims define preferred and advantageous embodiments of the present invention.

In the context of at least one embodiment of the present invention, a method is provided for capturing MR image data by WAY of a magnetic resonance installation. This method comprises:

capturing the MR image data relating to a predefined volume section of an examination object (e.g. a patient) by means of the magnetic resonance installation;

capturing image data of the predefined volume section by means of a true-to-original tomographic method;

comparing the MR image data with the image data; and

correcting the MR image data depending on the results of the comparison, such that the MR image data matches the image data as closely as possible.

In the context of at least one embodiment of the present invention, a further method is provided for capturing MR image data by way of a magnetic resonance installation. This further inventive method comprises:

capturing MR image data relating to a predefined volume section of an examination object (e.g. a patient) by means of the magnetic resonance installation, specific parameters being used during the capture of the MR image data (this comprising in particular a capture of MR raw data and a reconstruction of the MR image data from this MR raw data);

capturing image data of the predefined volume section by means of a true-to-original tomographic method;

comparing the MR image data with the image data;

modifying the parameters depending on the results of the comparison, such that when the MR image data of the predefined volume section is captured again, using the modified parameters in this case, the newly captured MR image data matches the image data as closely as possible; and

capturing the MR image data of the predefined volume section again, using the modified parameters.

In the context of at least one embodiment of the present invention, provision is also made for a combined MR/ET facility for capturing MR image data of a predefined volume section of an examination object. In this case, the MR/ET facility comprises a control unit for activating an emission detector of the MR facility and a magnetic resonance installation of the MR facility, and an image computing unit for receiving raw data of the predefined volume section, said raw data having been captured by the emission detector, and receiving MR raw data of the predefined volume section, said MR raw data having been recorded by the magnetic resonance installation, and for creating the MR image data from the MR raw data and image data from the raw data. In this case, the emission detector is so configured as to capture true-to-original tomographic raw data. The MR/ET facility is so configured as to compare the MR image data with the image data and to correct the MR image data depending on the results of this comparison, such that the MR image data matches the image data as closely as possible.

At least one embodiment of the present invention also describes a computer program product, in particular a computer program or software, which can be loaded into a memory of a programmable control or a computer unit of a combined MR/ET facility. Using the computer program product, all or various of the above-described embodiments of the inventive method can be executed when the computer program product runs in the control or control unit of the combined MR/ET facility. In this case, the computer program product might require programming resources such as libraries and help functions, for example, in order to realize the corresponding embodiments of the methods. In other words, the claim relating to the computer program product is intended to include in the scope of protection in particular a computer program or software by means of which one of the above described embodiments of the inventive methods can be executed and/or which executes said embodiment. In this case, the software can be a source code (e.g. C++) which remains to be compiled (translated) and linked or which merely needs to be interpreted, or an executable software code which merely needs to be loaded into the relevant computer unit for execution.

Lastly, at least one embodiment of the present invention discloses an electronically readable data medium, e.g. a DVD, a magnetic tape or a USB stick, on which is stored electronically readable control information, in particular software (see above). When this control information (software) is read from the data medium and stored in a control or computer unit of a combined MR/ET facility, all of the inventive embodiments of the above described methods can be performed.

### BRIEF DESCRIPTION OF THE DRAWINGS

The present invention is described in detail below on the basis of example embodiments according to the invention and with reference to the figures, in which:

FIG. 1 schematically illustrates a combined MR/PET facility according to an embodiment of the invention,

FIG. 2 illustrates a flow diagram of a first method according to an embodiment of the invention, and

FIG. 3 illustrates a flow diagram of a second method according to an embodiment of the invention.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. The use of similar or identical reference numbers in the various drawings is intended to indicate the presence of a similar or identical element or feature.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Before discussing example embodiments in more detail, it is noted that some example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed below, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks will be stored in a machine or computer readable medium such as a storage medium or non-transitory computer readable medium. A processor(s) will perform the necessary tasks.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the following description, illustrative embodiments may be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

Note also that the software implemented aspects of the example embodiments may be typically encoded on some form of program storage medium or implemented over some type of transmission medium. The program storage medium (e.g., non-transitory storage medium) may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The example embodiments not limited by these aspects of any given implementation.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

In the context of at least one embodiment of the present invention, a method is provided for capturing MR image data by WAY of a magnetic resonance installation. This method comprises:

capturing the MR image data relating to a predefined volume section of an examination object (e.g. a patient) by means of the magnetic resonance installation;

capturing image data of the predefined volume section by means of a true-to-original tomographic method;

comparing the MR image data with the image data; and

correcting the MR image data depending on the results of the comparison, such that the MR image data matches the image data as closely as possible.

In the context of at least one embodiment of the present invention, a tomographic method is understood to be an imaging method which determines the internal spatial structure of an object and depicts it in the form of an image (e.g. a sectional image). True-to-original means that geometric structures may be enlarged or reduced, rotated and/or mirrored in their entirety, but may not be represented or depicted in a distorted manner, and therefore length ratios and angles of the spatial structure are preserved in the image. Depending on the tomographic method, true-to-original can also signify length-preserving and angle-preserving in an absolute sense. If the tomographic method depicts the spatial structures in a length-preserving manner, a volume of the spatial structure that is to be represented can be represented (and therefore measured) precisely.

In the context of embodiments of the invention, comparing the MR image data and the image data is understood to comprise an examination of how the MR image data can be migrated or transformed into the image data. Such a procedure is known from the registration of two images. In this case, the registration is a method or a process for reconciling to the greatest possible extent one image (the MR image in the present case) with another image (the image created by the true-to-original topographical method in this case). To this end, provision is usually made for calculating a transformation by which the MR image or the MR image data is adapted as optimally as possible to the image or the image data. Unlike the registration, the comparison does not perform the registration, but merely determines corresponding data or information.

The correction of the MR image data depending on the results of the comparison can be performed, for example, so as to execute a registration of the MR image data with the image data, the results of the comparison therefore being used in order to adapt the MR image data as optimally as possible to the image data.

As a result of the MR image data being corrected by way of the image data as per the invention, the MR image data has improved location integrity or geometric accuracy after this correction. Furthermore, the correction of the MR image data results in an improved correspondence of the image points of the MR image data to the corresponding image points of the image data, this being particularly advantageous with regard to a fusion of the MR image data and the image data.

In the context of at least one embodiment of the present invention, a further method is provided for capturing MR image data by way of a magnetic resonance installation. This further inventive method comprises:

capturing MR image data relating to a predefined volume section of an examination object (e.g. a patient) by means of the magnetic resonance installation, specific parameters being used during the capture of the MR image data (this comprising in particular a capture of MR raw data and a reconstruction of the MR image data from this MR raw data);

capturing image data of the predefined volume section by means of a true-to-original tomographic method;

comparing the MR image data with the image data;

modifying the parameters depending on the results of the comparison, such that when the MR image data of the predefined volume section is captured again, using the modified parameters in this case, the newly captured MR image data matches the image data as closely as possible; and

capturing the MR image data of the predefined volume section again, using the modified parameters.

In the context of at least one embodiment of this further inventive method, the MR image data that is recorded using the modified parameters likewise has better geometric accuracy than is the case in the prior art (without modification of the parameters). This again results in a better match between the image points of the MR image data and the corresponding image points of the image data.

While the correction of the MR image data according to at least one embodiment of the inventive method is done in a quasi image-based manner, i.e. after a corresponding reconstruction of the raw data to produce the MR image data, the further inventive method involves a modification of parameters which can also be used during the reconstruction of the MR image data from the MR raw data, for example.

In the context of at least one embodiment of the further inventive method, it is possible to apply a warp correction, for example, wherein the parameters to be specified are parameters of said warp correction. These parameters are modified depending on the results of the comparison in such a way that the MR image data, which has been corrected with reference to the warp correction that is based on the correspondingly modified parameters, matches the image data as closely as possible.

In this case, a warp correction is understood to be any correction by which effects that negatively influence the geometric representational accuracy of the MR image data are at least moderated.

As indicated above, MR raw data can be captured in advance (e.g. by sampling the k-space) for the purpose of capturing the MR image. The MR image data is reconstructed from the MR raw data in this case, wherein the cited parameters are applied. Depending on the results of the comparison, these parameters are modified such that when the MR image data is reconstructed from the MR raw data again, using the modified parameters, the newly reconstructed MR image data matches the image data as closely as possible.

The parameters that are used can be correction parameters for correcting an MR distortion. The parameters for modeling and/or correcting gradient non-linearities or undesired basic field effects can be used in this case. In other words, provision is inventively made for the correction parameters to be specified and then applied to a prospective correction of MR distortions.

In particular, the specification of the parameters takes the form of a calibration measurement, which can advantageously be performed on the patient concerned.

Using the parameters that are applied for the reconstruction of the MR image data from the MR raw data, it is also possible e.g. to perform a correction of the MR raw data, this normally being captured as complex numbers (e.g. amplitude and phase). For example, these parameters can comprise a phase difference which is used to correct the phase of the MR raw data that is captured when sampling the k-space.

For the purpose of setting or specifying the parameters, a target function that is used to determine an image similarity between the MR image data and the image data can be defined, for example. The parameters are then modified in a type of control loop or iteration until the reconstruction of the MR image data by way of the parameters results in an optimum of the target function.

If the parameters include the phase difference, the invention offers two variants in relation to this phase difference:

1. The phase difference applies globally, i.e. the same phase difference is used for all MR raw data (for all k-space points).

2. A phase difference is used and specified individually for each k-space point. This second variant also comprises subvariants. For example, the same phase difference can be used for all k-space points of the same k-space row or k-space column. Or the same phase difference is used for those k-space points which have a predefined proximity relationship in the k-space.

In other words, only one parameter need be specified in the case of the first variant, namely the phase difference that is globally applied. In the case of the second variant, however, a dedicated phase difference must be specified for each k-space point or for a plurality of k-space points (which have a specific proximity relationship in the k-space). With regard to the second variant, use is made of smoothing in particular to ensure that the difference between the phase differences of two adjacent k-space points is no greater than a predefined threshold value.

According to at least one embodiment of the invention, the comparison of the MR image data with the image data involves examining how the MR image data can be migrated into the image data using a non-rigid registration, wherein this applies to both the inventive method and the further inventive method. In this case, a rigid registration is understood to be a registration in which the same shift vector (i.e. one shift vector only) for all image points is specified for each image point of the MR image. In the case of non-rigid or elastic registration, however, each image point of the MR image has a dedicated shift vector which is used to shift the corresponding image point in such a way that the MR image as closely as possible matches the image that was created by the true-to-original tomographic method.

In both embodiments of the inventive method and the further inventive method, those methods in which radiation is measured can be used as a true-to-original tomographic method. In this case, a distinction is made between methods in which said radiation is generated outside of the volume section that is to be represented, e.g. x-ray methods, and methods in which the radiation to be captured is generated inside the volume section that is to be represented (e.g. by injection of radioactive tracers), wherein this is known as emission computer tomography and includes e.g. PET (“positron emission tomography”) and SPECT (“single photon emission computed tomography”).

In both embodiments of the inventive method and the further inventive method, the MR image data and the image data are advantageously captured simultaneously.

The simultaneous capture of the MR image data and the image data is possible firstly because the magnetic resonance installation is independent of the true-to-original tomographic method. Secondly, the simultaneous capture of the MR image data and the image data has the advantage that there are no differences between the MR image data and the image data due to object movements which could occur if the MR image data and the image data were created at different time points.

The comparison of the MR image data with the image data can be done by way of anatomical features of the examination object (e.g. following a tracer injection), wherein these anatomical features must be visible in both the MR image data and the image data of the true-to-original tomographic method (e.g. must be present in the field of view in each case). The comparison can also be effected by way of markers (e.g. pellets that are filled with a tracer and are also visible in the MR images), wherein the markers here must again be present in the field of view of both methods (MR method and true-to-original tomographic method).

In the context of at least one embodiment of the present invention, provision is also made for a combined MR/ET facility for capturing MR image data of a predefined volume section of an examination object. In this case, the MR/ET facility comprises a control unit for activating an emission detector of the MR facility and a magnetic resonance installation of the MR facility, and an image computing unit for receiving raw data of the predefined volume section, said raw data having been captured by the emission detector, and receiving MR raw data of the predefined volume section, said MR raw data having been recorded by the magnetic resonance installation, and for creating the MR image data from the MR raw data and image data from the raw data. In this case, the emission detector is so configured as to capture true-to-original tomographic raw data. The MR/ET facility is so configured as to compare the MR image data with the image data and to correct the MR image data depending on the results of this comparison, such that the MR image data matches the image data as closely as possible.

In the context of at least one embodiment of the present invention, provision is also made for a further combined MR/ET facility for capturing MR image data of a predefined volume section of an examination object. In this case, the MR/ET facility comprises a control unit for activating an emission detector of the MR/ET facility and a magnetic resonance installation of the MR/ET facility, and an image computing unit for receiving raw data of the predefined volume section, said raw data having been captured by the emission detector, and receiving MR raw data of the predefined volume section, said MR raw data having been recorded by the magnetic resonance installation, and for creating the MR image data from the MR raw data, depending on parameters, and creating image data from the raw data. In this case, the emission detector is so configured as to capture true-to-original tomographic raw data. The MR/ET facility is so configured as to set or modify the parameters depending on results of a comparison between the MR image data and the image data such that, after the MR image data has been created from the MR raw data again (using the modified parameters), the newly created MR image data matches the image data as closely as possible.

According to at least one embodiment of the invention, a combined MR/ET facility is understood in this case to be a facility that comprises a combination of a magnetic resonance tomograph and an emission computer tomograph (e.g. a positron emission tomograph) or an x-ray system. In other words, a combined MR/ET facility is understood to be a facility which, in addition to a magnetic resonance tomograph, comprises an installation that can perform a true-to-original tomographic method (see above). Such an installation can therefore also be an installation that itself generates the radiation by means of which the volume section is irradiated and represented, as is the case when using an x-ray system, for example.

In this case, the advantages of the inventive combined MR/ET facilities correspond essentially to the advantages of the inventive method, which are explained in detail above and are therefore not repeated here.

At least one embodiment of the present invention also describes a computer program product, in particular a computer program or software, which can be loaded into a memory of a programmable control or a computer unit of a combined MR/ET facility. Using the computer program product, all or various of the above-described embodiments of the inventive method can be executed when the computer program product runs in the control or control unit of the combined MR/ET facility. In this case, the computer program product might require programming resources such as libraries and help functions, for example, in order to realize the corresponding embodiments of the methods. In other words, the claim relating to the computer program product is intended to include in the scope of protection in particular a computer program or software by means of which one of the above described embodiments of the inventive methods can be executed and/or which executes said embodiment. In this case, the software can be a source code (e.g. C++) which remains to be compiled (translated) and linked or which merely needs to be interpreted, or an executable software code which merely needs to be loaded into the relevant computer unit for execution.

Lastly, at least one embodiment of the present invention discloses an electronically readable data medium, e.g. a DVD, a magnetic tape or a USB stick, on which is stored electronically readable control information, in particular software (see above). When this control information (software) is read from the data medium and stored in a control or computer unit of a combined MR/ET facility, all of the inventive embodiments of the above described methods can be performed.

In summary, at least one embodiment of the inventive idea resides in utilizing the geometric information from devices that provide a geometrically correct representation, e.g. PET, for the purpose of correcting MR image data, this being possible as a result of the precise spatial assignment between the devices (e.g. PET and MR) since both represent the same volume section. In this case, the correction of the MR image data can be image-based or raw data-based. The image-based correction can be effected firstly by means of a retrospective registration of the MR image with the PET image, wherein the PET image is used as a true-to-original reference for registration onto the MR image, the registration being non-rigid in particular. Secondly, the image-based correction can be effected by way of an adaptation of the warp correction using the geometric information that is obtained from the PET image. In the case of raw data-based correction, the geometric information that is obtained from the PET image can be used during the MR reconstruction or to correct the MR raw data (e.g. in the form of a phase correction).

At least one embodiment of the present invention is suitable for e.g. correlation studies (a combination of fMRI (functional MR imaging) and dynamic PET), for radiotherapy planning, for operation planning and also for MR-aided biopsy. Moreover, the present invention allows the accuracy of MR images to be improved, such that e.g. an exact volumetric evaluation can also be performed on the basis of the MR images that are created according to at least one embodiment of the invention. Embodiments of the present invention are obviously not restricted to these preferred fields of application, since the present invention can also be used generally to improve the geometric accuracy of MR images, thereby allowing greater location integrity of the MR images.

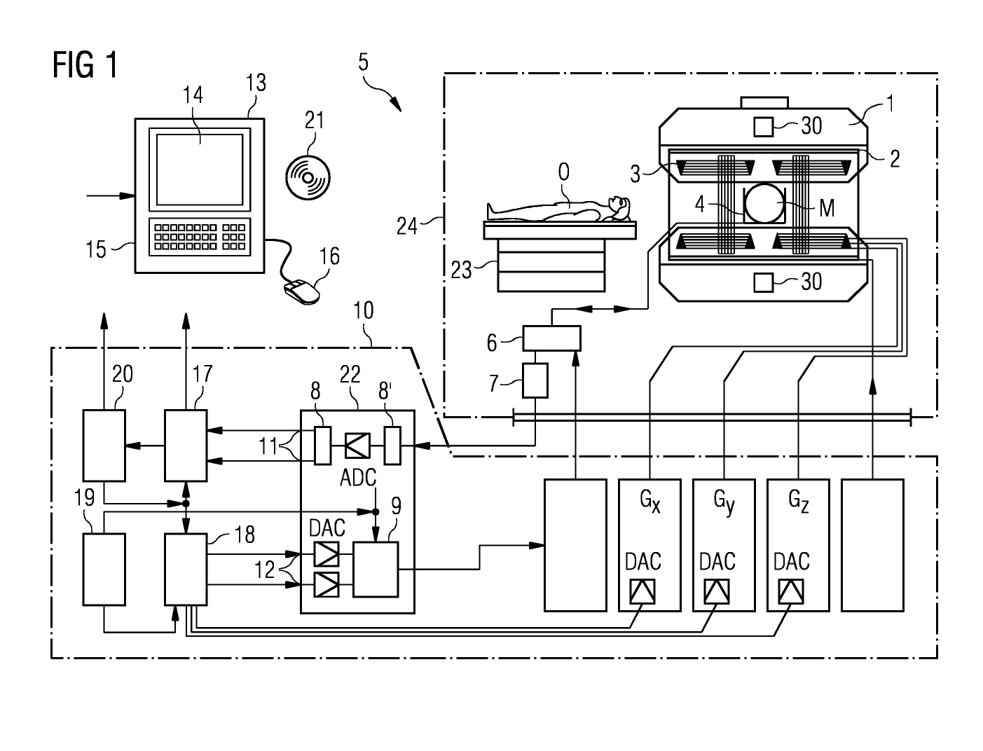

FIG. 1 shows a schematic illustration of a combined MR/PET facility 5, which comprises a positron emission detector 30 and a magnetic resonance installation 24. In this case, a basic field magnet 1 of the magnetic resonance installation 24 generates a temporally constant strong magnetic field in order to polarize or align the nuclear spin in an examination region of an object O, such as e.g. a part to be examined in a human body which is lying on a table 23 and is pushed into the magnetic resonance installation 24 for the purpose of creating an image. The nuclear spin resonance measurement requires a high level of homogeneity of the basic magnetic field, and said homogeneity is defined in a typically spherical measured volume M, in which those parts of the human body that are to be examined are arranged for the purpose of capturing the MR data. In order to meet the homogeneity requirements and in particular to eliminate temporally invariable influences, so-called shim plates of ferromagnetic material are attached at suitable locations. Temporally variable influences are eliminated by means of shim coils 2.

A cylindrical gradient coil system 3 including three partial windings is used in the basic field magnet 1. Each partial winding is supplied, by way of an amplifier, with current for generating a linear (and temporally variable) gradient field in the relevant direction of the Cartesian system of coordinates. In this case, the first partial winding of the gradient field system 3 generates a gradient Gx in an x-direction, the second partial winding generates a gradient Gy in a y-direction and the third partial winding generates a gradient Gz in a z-direction. The amplifier comprises a digital-analog converter, which is activated by a sequence control 18 for generating gradient pulses at the correct time.

The gradient field system 3 contains one or more high-frequency antennas 4, which convert the high-frequency pulses that are emitted by a high-frequency power amplifier into a magnetic alternating field in order to excite the nuclei and align the nuclear spins of the object O, or the region thereof, that is to be examined. Each high-frequency antenna 4 consists of one or more HF transmit coils and one or more HF receive coils in the form of an annular, preferably linear or matrix-type arrangement of component coils. The HF receive coils of the high-frequency antenna 4 are also used to convert the alternating field that is produced by the precessing nuclear spins, i.e. usually the nuclear spin echo signals that are produced by a pulse signal from one or more high-frequency pulses and one or more gradient pulses, into a voltage (measurement signal) that is supplied via an amplifier 7 to a high-frequency receive channel 8 of a high-frequency system 22. The high-frequency system 22 further comprises a transmit channel 9 in which the high-frequency pulses for exciting the magnetic nuclear resonance are generated. In this case, the respective high-frequency pulses are represented digitally as a sequence of complex numbers in the sequence control 18 as a result of a pulse sequence that is specified by the installation computer 20. This number sequence is supplied as a real part and an imaginary part via an input 12 in each case to a digital-analog converter in the high-frequency system 22 and thence to a transmit channel 9. In the transmit channel 9, the pulse sequences are modulated onto a high-frequency carrier signal, whose basic frequency corresponds to the resonance frequency of the nuclear spin in the measured volume.

The changeover from transmit mode to receive mode is effected by way of a transmit-receive filter 6. The HF transmit coils of the high-frequency antenna(s) 4 beam the high-frequency pulses for exciting the nuclear spin into the measured volume M, and resulting echo signals are sampled via the HF receive coil(s). The correspondingly obtained nuclear resonance signals are demodulated in a phase-sensitive manner onto an intermediary frequency (wherein e.g. correction parameters can be applied) in the receive channel 8′ (first demodulator) of the high-frequency system 22, and digitized in the analog-digital converter (ADC). This signal is then demodulated onto the frequency 0. The demodulation onto the frequency 0 and the separation into a real part and an imaginary part takes place in a second demodulator 8 after digitization in the digital domain. An MR image (wherein correction parameters can likewise be applied) and a PET image (see below) are reconstructed by an image computer 17 from the measured data that is obtained thus. The measured data, the image data and the control programs are managed by the installation computer 20. On the basis of specifications from control programs, the sequence control 18 monitors the generation of the relevant desired pulse sequences and the corresponding sampling of the k-space. In particular, the sequence control 18 controls the timely switching of the gradients, the emission of the high-frequency pulses with defined phase amplitude, and the receipt of the nuclear resonance signals in this case. The time base for the high-frequency system 22 and the sequence control 18 is provided by a synthesizer 19.

As explained above, the MR/PET facility 5 comprises a positron emission detector 30, which is usually of annular design. The tracers that are used in the case of PET are marked by a positron source. When this positron source decays in the tissue of the patient O, two γ-quantums are generated by annihilation in the vicinity of the location of the corresponding positron emission, and fly apart in opposite directions. If these two γ-quantums are measured by two opposing detector elements of the positron emission detector 30 within a predefined coincidence time period, the location of the annihilation can be established at a position on the connection line between said two detector elements.

The positron emission detector 30 is used to capture the PET data from which the PET image is then generated in the image computer 17. According to an embodiment of the invention, the PET image is compared with the MR image in the image computer 17, in order to create corresponding results of this comparison and adapt the MR image to the PET image.

The selection of corresponding control programs for generating the MR images and PET images, for comparing and correcting the MR images or the above cited correction parameters, which are stored e.g. on a DVD 21, and the depiction of the generated MR images is coordinated via a terminal 13 comprising a keyboard 15, a mouse 16 and a display screen 14.

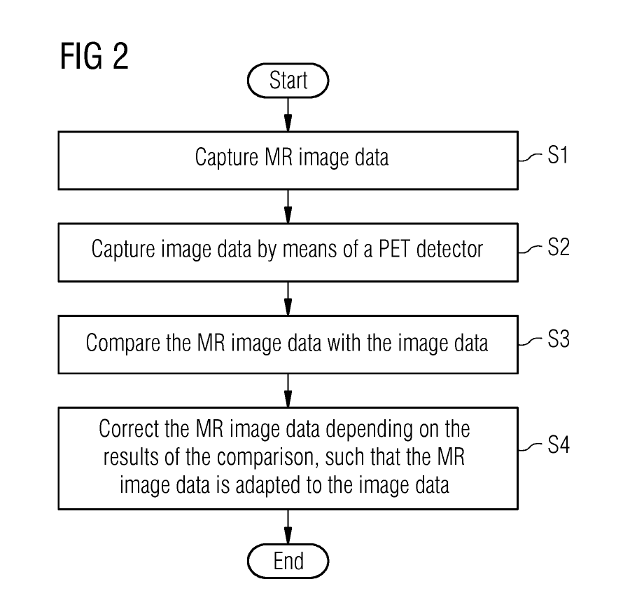

FIG. 2 illustrates a flowchart of a first method according to an embodiment of the invention.

While the MR image data is captured in the first step S1, PET image data is simultaneously captured by way of a PET detector in the second step S2. The MR image data is compared with the PET image data in the following step S3. This comparison includes determining a transformation by which the MR image data can be migrated into the PET image data. However, this comparison can also include adapting a warp correction (based on the geometric information of the PET image data), wherein the MR image data can be corrected correspondingly by way of the warp correction in order to correspond to the PET image data in terms of geometric accuracy.

In the final step S4, the MR image data is corrected depending on the results of the comparison, such that the MR image data matches the PET image data as closely as possible. For example, the above-cited transformation or the above cited warp correction can be applied to the original MR image data for this purpose.

The steps S3 and S4 in FIG. 2 can also be replaced by a registration of the MR image data with the PET image data. The PET image is used as a true-to-original reference for registration of the MR image in this case, said registration being non-rigid in particular.

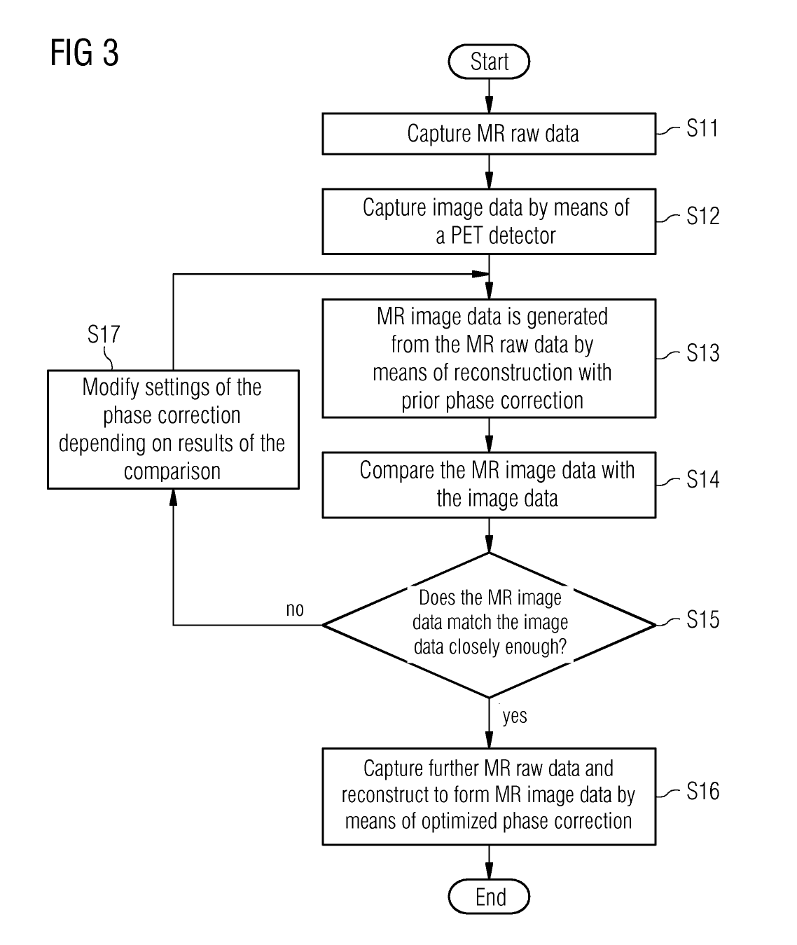

FIG. 3 illustrates a flowchart of a second method according to an embodiment of the invention.

In the first step S11, raw data is captured by means of the magnetic resonance installation MR, while PET image data is simultaneously captured by way of the PET detector in the step S12. In the step S13, the phase of the MR raw data is corrected before the MR image data is reconstructed from the MR raw data.

In the following step S14, the MR image data is compared with the PET image data. This can be realized e.g. by means of a function that takes the MR image data and the PET image data as an input and outputs a measure of similarity as an output. If the match between the MR image data and the PET image data is insufficiently close in the following step S15 (i.e. the measure of similarity is lower than a threshold value), the second method branches to the step S17.

In this step S17, depending on the comparison of the MR image data with the PET image data in the step S14, the settings of the phase correction are changed such that better results can be expected in respect of the match between the MR image data and the PET image data in the next program loop (execution of the steps S13 to S15). If the phase correction in the step S3 is effected by way of adding a globally applicable phase difference, for example, this phase difference is modified in the step S17 accordingly.

If the MR image data matches the PET image data sufficiently closely in the following run (see step S15), the second method branches to the step S16, in which further MR raw data is captured and is reconstructed by way of the now optimal phase correction to provide MR image data.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a tangible computer readable medium and is adapted to perform any one of the aforementioned methods when run on a computer device (a device including a processor). Thus, the tangible storage medium or tangible computer readable medium, is adapted to store information and is adapted to interact with a data processing facility or computer device to execute the program of any of the above mentioned embodiments and/or to perform the method of any of the above mentioned embodiments.

The tangible computer readable medium or tangible storage medium may be a built-in medium installed inside a computer device main body or a removable tangible medium arranged so that it can be separated from the computer device main body. Examples of the built-in tangible medium include, but are not limited to, rewriteable non-volatile memories, such as ROMs and flash memories, and hard disks. Examples of the removable tangible medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for capturing MR image data by way of a magnetic resonance installation, comprising:
capturing the MR image data relating to a volume section of an examination object;
capturing image data of the volume section by way of a true-to-original tomographic method;
comparing the MR image data with the image data; and
correcting the MR image data depending on at least one result of the comparison, such that the corrected MR image data will match the image data as closely as possible.

2. A method for capturing MR image data by way of a magnetic resonance installation, comprising:
capturing the MR image data relating to a volume section of an examination object, wherein parameters are used during the capturing of the MR image data;
capturing image data of the volume section by way of a true-to-original tomographic method;
comparing the MR image data with the image data;
modifying the parameters depending on at least one result of the comparison, such that after the MR image data of the volume section is captured again using the modified parameters, the MR image data captured again will match the image data as closely as possible; and
capturing the MR image data of the volume section again using the modified parameters.

3. The method as claimed in claim 2, wherein a warp correction is used during the capturing of the MR image data, wherein the parameters are parameters of the warp correction, and wherein the parameters are modified depending on the comparison, and therefore the MR image data is modified by way of the warp correction using the modified parameters, such that the modified MR image data matches the image data as closely as possible.

4. The method as claimed in claim 2, wherein MR raw data is captured during the capturing of the MR image data, wherein the MR image data is reconstructed from the MR raw data, wherein the parameters are parameters which are applied during the reconstruction of the MR image data, and wherein the parameters are modified depending on the comparison in such a way that, when the MR image data is reconstructed again from the MR raw data using the modified parameters, the reconstructed MR image data matches the image data as closely as possible.

5. The method as claimed in claim 4, wherein the parameters comprise a phase difference by which a phase of the MR raw data is corrected.

6. The method as claimed in claim 5, wherein the phase difference is specified as an individual phase difference per k-space point, or wherein the phase difference is specified globally as the same phase difference for all k-space points.

7. The method as claimed in claim 1, wherein the comparison is part of a non-rigid registration that is used to create a transformation by which the MR image data are migrateable into the image data.

8. The method as claimed in claim 1, wherein the true-to-original tomographic method is a positron emission tomography.

9. The method as claimed in claim 1, wherein the capture of the MR image data and the capture of the image data take place simultaneously.

10. The method as claimed in claim 1, wherein the comparison is done with reference to anatomical features of the examination object, the anatomical features being visible to both the magnetic resonance installation and the true-to-original tomographic method, or wherein the comparison is done with reference to markers which are visible to both the magnetic resonance installation and the true-to-original tomographic method.

11. A combined MR/ET facility for capturing MR image data of a volume section of an examination object, the MR/ET facility comprising:
a control unit configured to activate an emission detector of the MR/ET facility and configured to activate a magnetic resonance installation of the MR/ET facility; and
an image computing unit configured to receive raw data of the volume section, the raw data being captured by the emission detector; configured to receive MR raw data of the volume section, the MR raw data being recorded by the magnetic resonance installation; and configured to create the MR image data from the MR raw data and image data from the ET data,
wherein the emission detector is so configured as to capture true-to-original tomographic raw data,
wherein the MR/ET facility is so configured as to compare the MR image data with the image data, and
wherein the MR/ET facility is so configured as to correct the MR image data depending on at least one result of the comparison, such that the MR image data will match the image data as closely as possible.

12. A combined MR/ET facility for capturing MR image data of a volume section of an examination object, the MR/ET facility comprising:
a control unit configured to activate an emission detector of the MR/ET facility and configured to activate a magnetic resonance installation of the MR/ET facility; and
an image computing unit configured to capture image data by way of the emission detector or configured to capture MR image data by way of the magnetic resonance installation depending on parameters,
wherein the emission detector is so configured as to capture true-to-original tomographic image data,
wherein the MR/ET facility is so configured as to compare the MR image data with the image data,
wherein the MR/ET facility is so configured that, depending on at least one result of the comparison, the MR/ET facility is configured to modify the parameters in such a way that, after the MR image data of the volume section is captured again using the modified parameters, the captured MR image data captured again will match the image data as closely as possible.

13. The combined MR/ET facility as claimed in claim 11, wherein the combined MR/ET facility is a combined MR/PET facility.

14. The combined MR/ET facility as claimed in claim 11, wherein the combined MR/ET facility is so configured as to carry out
capturing the MR image data relating to a volume section of an examination object;
capturing image data of the volume section by way of a true-to-original tomographic method;
comparing the MR image data with the image data; and
correcting the MR image data depending on at least one result of the comparison, such that the corrected MR image data will match the image data as closely as possible.

15. A computer program product which comprises a program and is loadable directly into a memory of a programmable control unit of a combined MR/ET facility, including program segments for executing all of the steps of the method as claimed in claim 1 when the program is executed in a control unit of the combined MR/ET facility.

16. An electronically readable data medium on which is stored electronically readable control information that is so configured as to carry out the method as claimed in claim 1 when executed when the data medium is used in a control unit of a combined MR/ET facility.

17. The method as claimed in claim 3, wherein MR raw data is captured during the capturing of the MR image data, wherein the MR image data is reconstructed from the MR raw data, wherein the parameters are parameters which are applied during the reconstruction of the MR image data, and wherein the parameters are modified depending on the comparison in such a way that, when the MR image data is reconstructed again from the MR raw data using the modified parameters, the reconstructed MR image data matches the image data as closely as possible.

18. The method as claimed in claim 3, wherein the parameters comprise a phase difference by which a phase of the MR raw data is corrected.

19. The method as claimed in claim 18, wherein the phase difference is specified as an individual phase difference per k-space point, or wherein the phase difference is specified globally as the same phase difference for all k-space points.

20. The method as claimed in claim 2, wherein the comparison is part of a non-rigid registration that is used to create a transformation by which the MR image data are migrateable into the image data.

21. The method as claimed in claim 2, wherein the true-to-original tomographic method is a positron emission tomography.

22. The method as claimed in claim 2, wherein the capture of the MR image data and the capture of the image data take place simultaneously.

23. The method as claimed in claim 2, wherein the comparison is done with reference to anatomical features of the examination object, the anatomical features being visible to both the magnetic resonance installation and the true-to-original tomographic method, or wherein the comparison is done with reference to markers which are visible to both the magnetic resonance installation and the true-to-original tomographic method.

24. The combined MR/ET facility as claimed in claim 12, wherein the combined MR/ET facility is a combined MR/PET facility.

25. The combined MR/ET facility as claimed in claim 12, wherein the combined MR/ET facility is so configured as to carry out
capturing the MR image data relating to a volume section of an examination object, wherein parameters are used during the capturing of the MR image data;
capturing image data of the volume section by way of a true-to-original tomographic method;
comparing the MR image data with the image data;
modifying the parameters depending on at least one result of the comparison, such that after the MR image data of the volume section is captured again using the modified parameters, the MR image data captured again will match the image data as closely as possible; and
capturing the MR image data of the volume section again using the modified parameters.

26. A computer program product which comprises a program and is loadable directly into a memory of a programmable control unit of a combined MR/ET facility, including program segments for executing all of the steps of the method as claimed in claim 2 when the program is executed in a control unit of the combined MR/ET facility.

27. An electronically readable data medium on which is stored electronically readable control information that is so configured as to carry out the method as claimed in claim 2 when executed when the data medium is used in a control unit of a combined MR/ET facility.

28. A computer readable medium including program segments for, when executed on a computer device, causing the computer device to implement the method of claim 1.

29. A computer readable medium including program segments for, when executed on a computer device, causing the computer device to implement the method of claim 2.
